(19) United States
(12) Patent Application Publication
(10) Pub. No.: US 2026/0344412 A1
(43) Pub. Date: Oct. 29, 2026

(54) SEMICONDUCTOR DEVICE STRUCTURE WITH CONDUCTIVE LAYER AND METHOD FOR FORMING THE SAME

(71) Applicant: Taiwan Semiconductor Manufacturing Company, Ltd., Hsinchu (TW)

(72) Inventors: Pin-Shun DING, Taichung City (TW); Tzu-Ting LIU, Taoyuan City (TW); Hsiang-Ku SHEN, Hsinchu City (TW); Ying-Han CHIOU, Tainan City (TW)

(21) Appl. No.: 19/189,376

(22) Filed: Apr. 25, 2025

(51) Int. Cl. H10W 20/40; H10D 1/00; H10D 1/68; H10W 20/00; H10W 20/41; H10W 20/42

(52) U.S. Cl. CPC H10W 20/496; H10D 1/041; H10D 1/692; H10W 20/056; H10W 20/075; H10W 20/42; H10W 20/435

(57) ABSTRACT

A method for forming a semiconductor device structure is provided. The method includes forming a conductive layer over a substrate. The method includes forming a dielectric layer over the conductive layer and the substrate. The method includes forming a first electrode over the dielectric layer and in the trench. The method includes forming a first dielectric film over the first electrode. The method includes forming a second electrode over the first dielectric film. The method includes forming a first conductive plug passing through the first electrode, the dielectric layer, and the conductive layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1M are cross-sectional views of various stages of a process for forming a semiconductor device structure, in accordance with some embodiments.

FIG. 1A-1 is a top view of the semiconductor device structure of FIG. 1A, in accordance with some embodiments.

FIG. 1B-1 is a top view of the semiconductor device structure of FIG. 1B, in accordance with some embodiments.

FIG. 1C-1 is a top view of the semiconductor device structure of FIG. 1C, in accordance with some embodiments.

FIG. 1D-1 is a top view of the semiconductor device structure of FIG. 1D, in accordance with some embodiments.

FIG. 1E-1 is a top view of the semiconductor device structure of FIG. 1E, in accordance with some embodiments.

FIG. 1F-1 is a top view of the semiconductor device structure of FIG. 1F, in accordance with some embodiments.

FIG. 1H-1 is a top view of the semiconductor device structure of FIG. 1H, in accordance with some embodiments.

FIG. 1I-1 is a top view of the semiconductor device structure of FIG. 1I, in accordance with some embodiments.

FIG. 1J-1 is a top view of the semiconductor device structure of FIG. 1J, in accordance with some embodiments.

FIG. 1K-1 is a top view of the semiconductor device structure of FIG. 1K, in accordance with some embodiments.

FIG. 1L-1 is a top view of the semiconductor device structure of FIG. 1L, in accordance with some embodiments.

FIG. 1M-1 is a top view of the semiconductor device structure of FIG. 1M, in accordance with some embodiments.

FIG. 2 is a top view of a semiconductor device structure, in accordance with some embodiments.

FIG. 3 is a top view of a semiconductor device structure, in accordance with some embodiments.

FIG. 4 is a top view of a semiconductor device structure, in accordance with some embodiments.

FIG. 5 is a top view of a semiconductor device structure, in accordance with some embodiments.

FIG. 6 is a top view of a semiconductor device structure, in accordance with some embodiments.

FIG. 7 is a cross-sectional view of a semiconductor device structure, in accordance with some embodiments.

FIG. 8 is a top view of a semiconductor device structure, in accordance with some embodiments.

FIG. 9 is a top view of a semiconductor device structure, in accordance with some embodiments.

FIG. 10A is a cross-sectional view of a semiconductor device structure, in accordance with some embodiments.

FIG. 10B is a top view of a first capacitor of the semiconductor device structure of FIG. 10A, in accordance with some embodiments.

FIG. 10C is a top view of a second capacitor of the semiconductor device structure of FIG. 10A, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as "substantially parallel" or "substantially perpendicular" may be interpreted as not to exclude insignificant deviation from the specified arrangement and may include for example deviations of up to 10°. The word "substantially" does not exclude "completely" e.g. a composition which is "substantially free" from Y may be completely free from Y.

The term "about" may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term "about" in relation to a numerical value x may mean x ±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

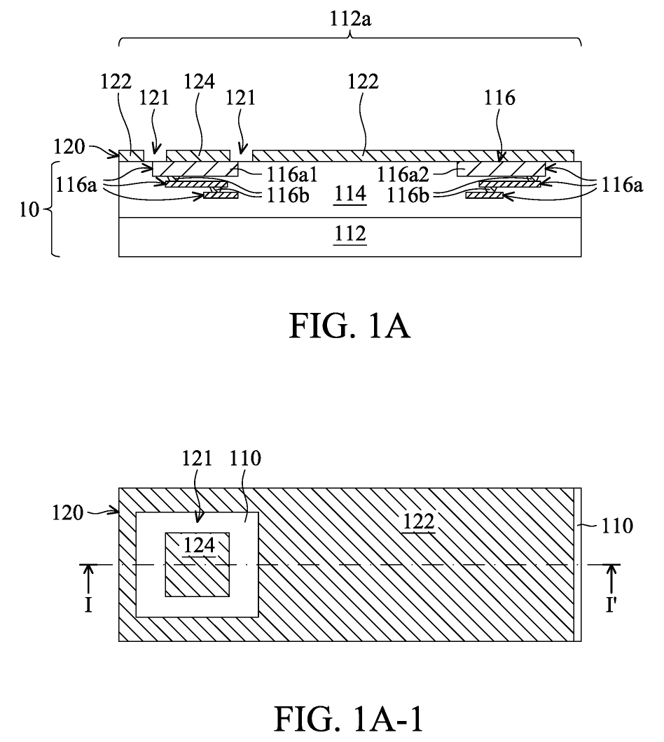

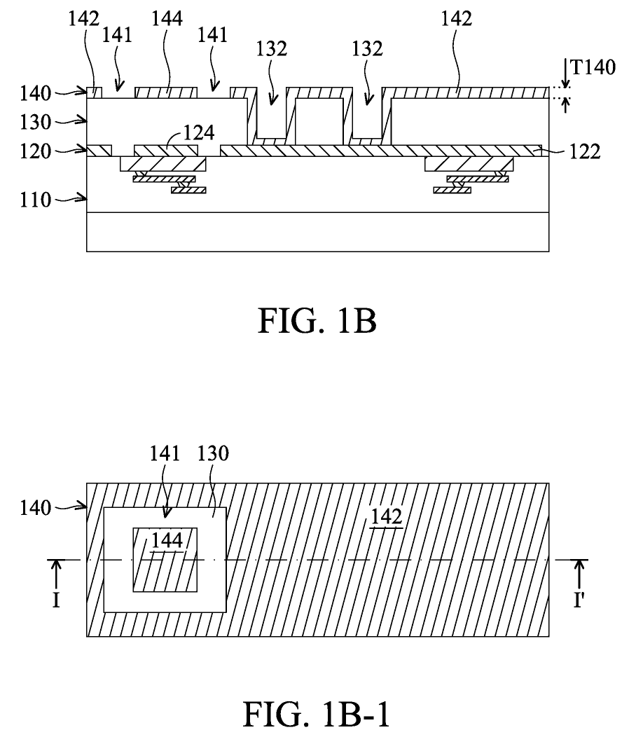

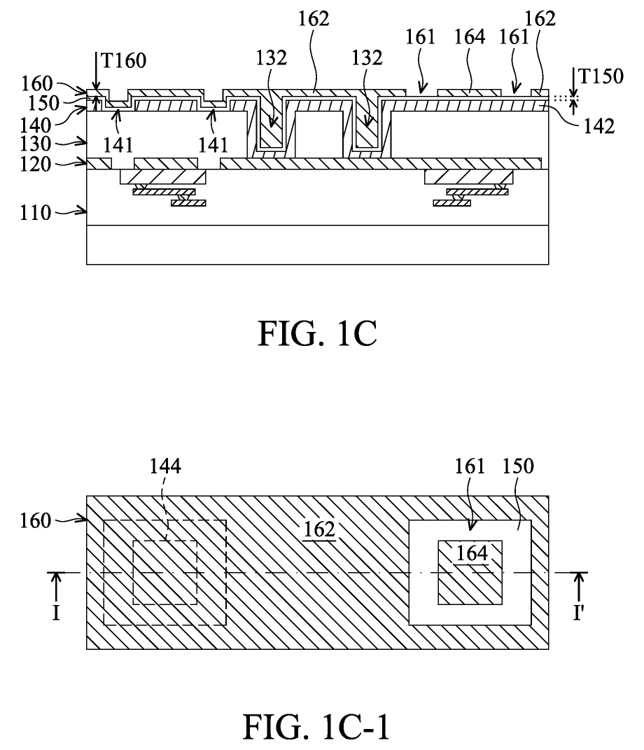

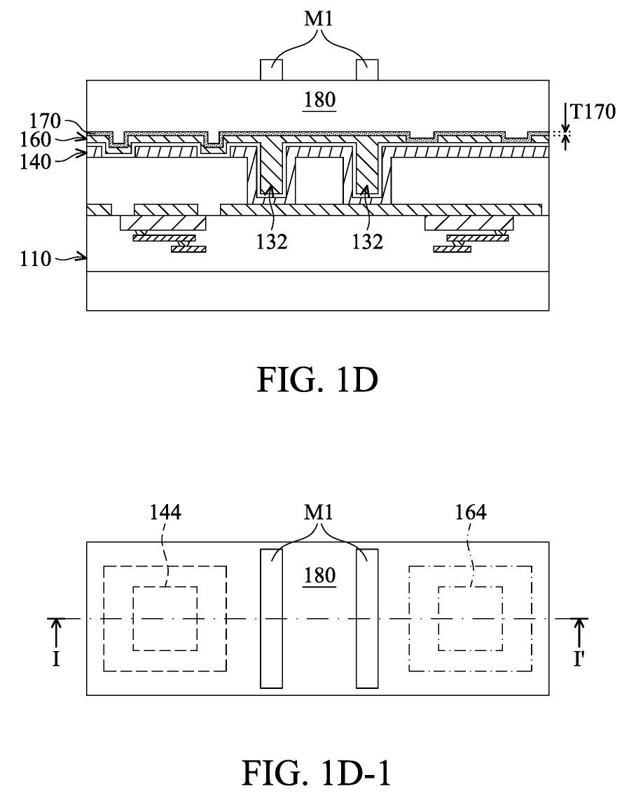

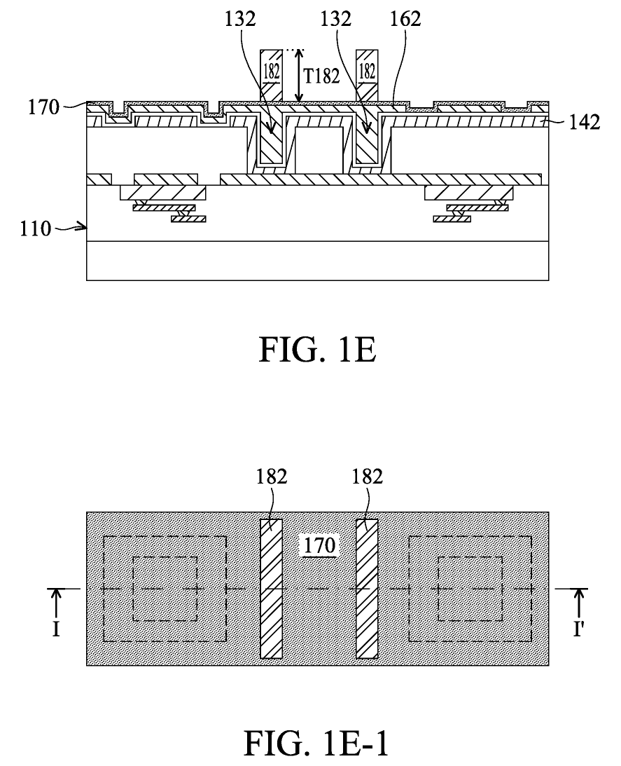

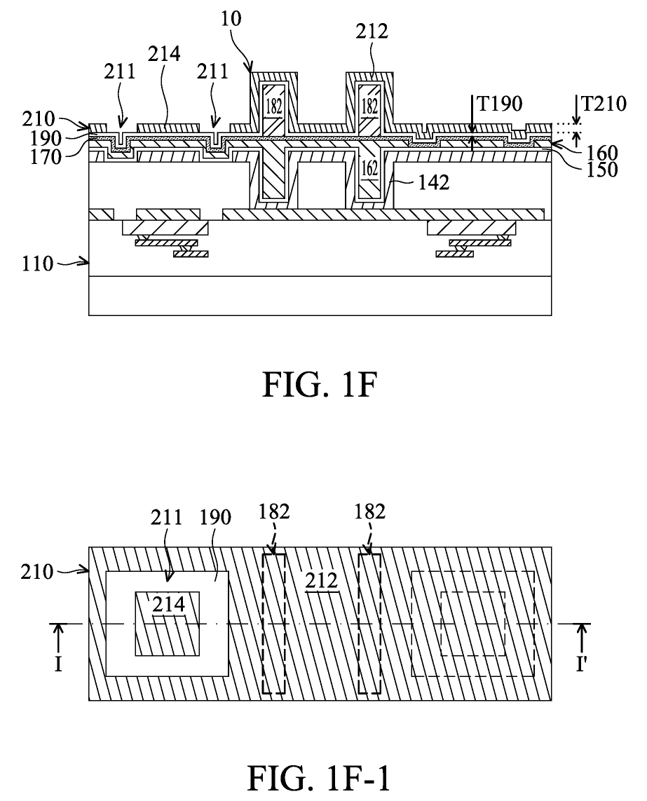

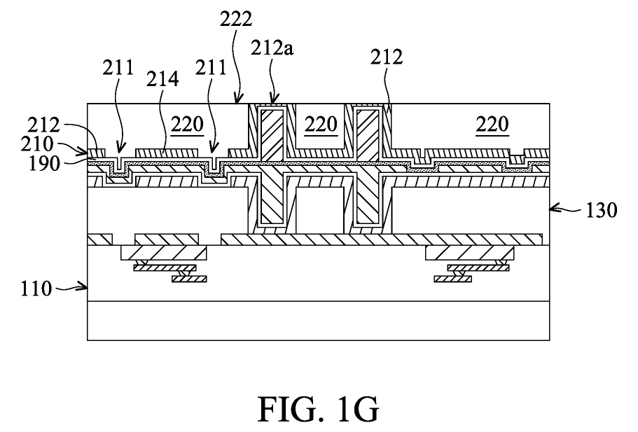

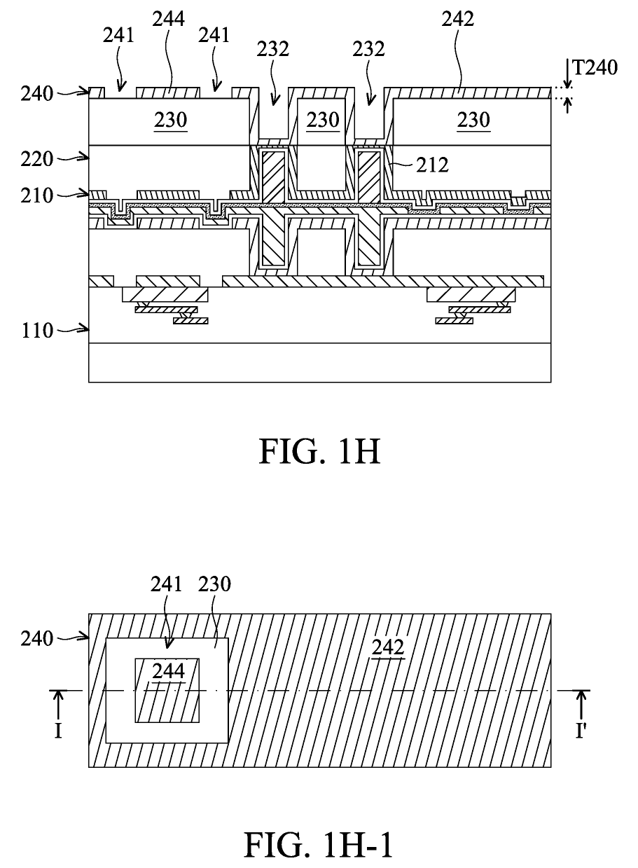

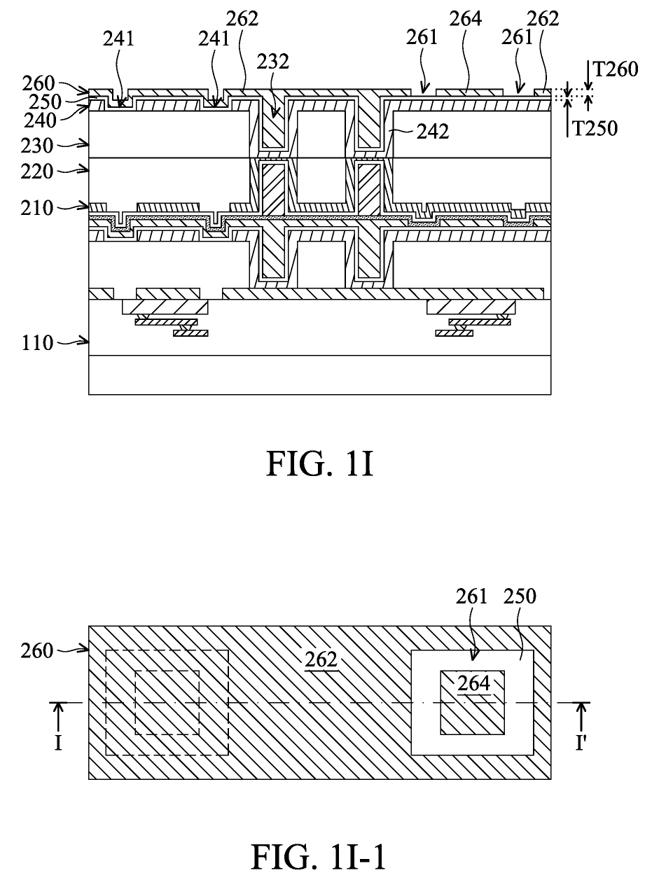

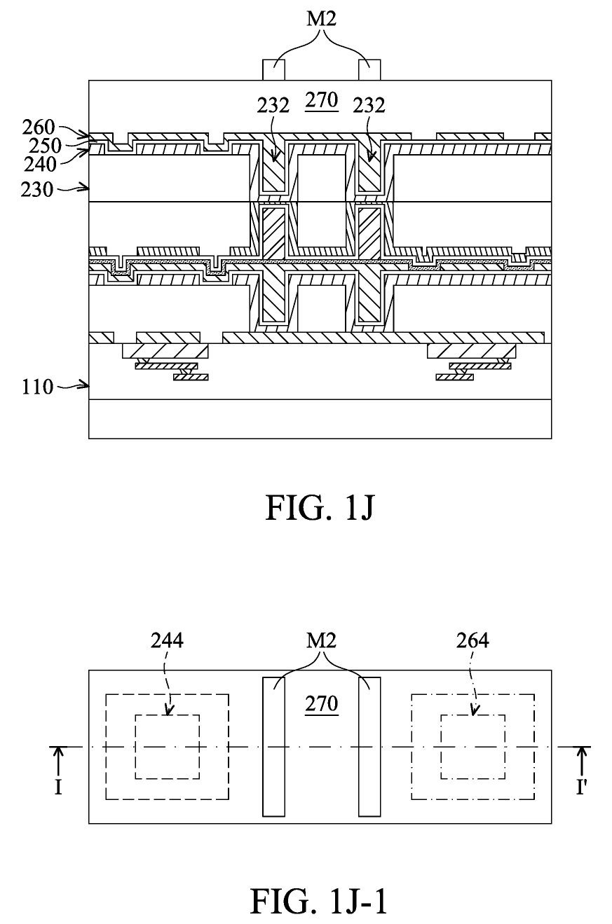

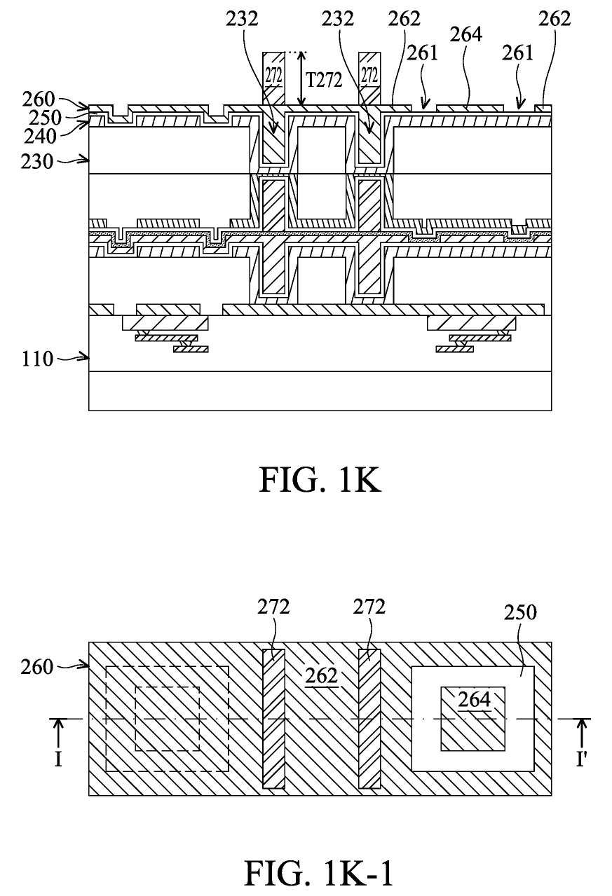

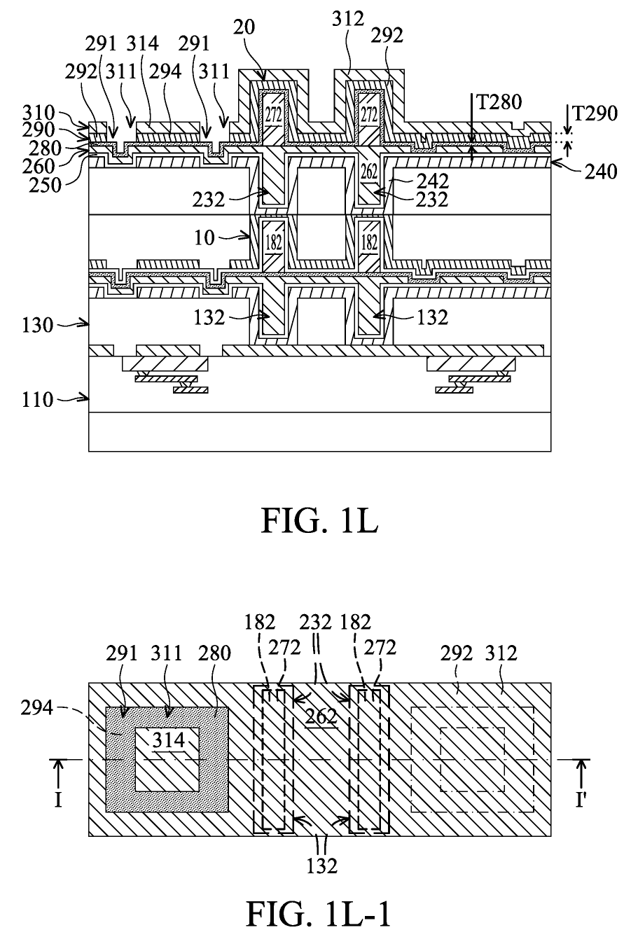

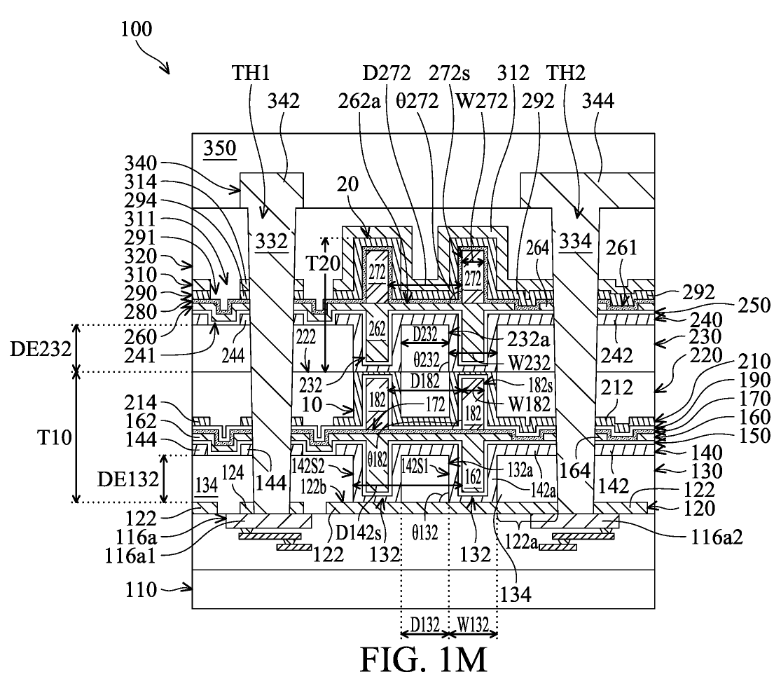

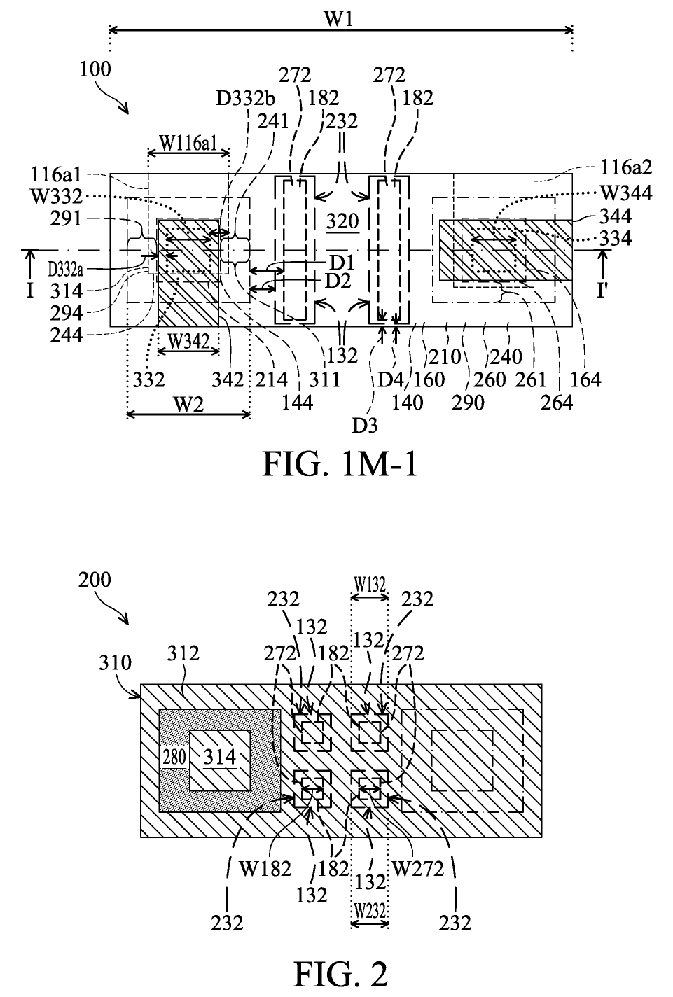

FIGS. 1A-1M are cross-sectional views of various stages of a process for forming a semiconductor device structure, in accordance with some embodiments. FIG. 1A-1 is a top view of the semiconductor device structure of FIG. 1A, in accordance with some embodiments. FIG. 1A is a cross-sectional view illustrating the semiconductor device structure along a sectional line I-I’ in FIG. 1A-1, in accordance with some embodiments.

As shown in FIGS. 1A and 1A-1, a substrate 110 is provided, in accordance with some embodiments. The substrate 110 includes a semiconductor substrate 112, a dielectric structure 114, and an interconnect structure 116, in accordance with some embodiments. The semiconductor substrate 112 includes, for example, a semiconductor wafer (such as a silicon wafer) or a portion of a semiconductor wafer.

In some embodiments, the semiconductor substrate 112 is made of an elementary semiconductor material including silicon or germanium in a single crystal structure, a polycrystal structure, or an amorphous structure. In some other embodiments, the semiconductor substrate 112 is made of a compound semiconductor, such as silicon carbide, gallium arsenide, gallium phosphide, indium phosphide, indium arsenide, an alloy semiconductor, such as SiGe or GaAsP, or a combination thereof.

The semiconductor substrate 112 may also include multi-layer semiconductors, semiconductor on insulator (SOI) (such as silicon on insulator or germanium on insulator), or a combination thereof. In some embodiments, the semiconductor substrate 112 is a device wafer that includes various device elements.

In some embodiments, the various device elements are formed in and/or over the semiconductor substrate 112. The device elements are not shown in figures for the purpose of simplicity and clarity. Examples of the various device elements include active devices, passive devices, other suitable elements, or a combination thereof.

The active devices may include transistors or diodes (not shown) formed at a surface of the semiconductor substrate 112. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate 112. The isolation features are used to surround active regions and electrically isolate various device elements formed in and/or over the semiconductor substrate 112 in the active regions. In some embodiments, the isolation features include shallow trench isolation (STI) features, local oxidation of silicon (LOCOS) features, other suitable isolation features, or a combination thereof.

As shown in FIGS. 1A and 1A-1, the dielectric structure 114 is formed over the semiconductor substrate 112, in accordance with some embodiments. The dielectric structure 114 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric structure 114 includes a low-k material or a porous dielectric material having a k-value which is lower than that of silicon oxide, or lower than about 3.0 or about 2.5, in accordance with some embodiments.

The dielectric structure 114 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIGS. 1A and 1A-1, the interconnect structure 116 is formed in the dielectric structure 114, in accordance with some embodiments. The interconnect structure 116 is over a device region 112a of the semiconductor substrate 112, in accordance with some embodiments. The interconnect structure 116 includes wiring layers 116a and conductive vias 116b, in accordance with some embodiments.

The wiring layers 116a and the conductive vias 116b are in the dielectric structure 114, in accordance with some embodiments. The conductive vias 116b are electrically connected between the wiring layers 116a and the devices formed at the semiconductor substrate 112, in accordance with some embodiments. The wiring layers 116a include metal lines 116a1 and 116a2, in accordance with some embodiments.

The wiring layers 116a and the conductive vias 116b are made of a conductive material, such as metal (e.g., titanium, copper, nickel, aluminum, gold, silver, tin, or tungsten) or alloys thereof, in accordance with some embodiments.

The wiring layers 116a and the conductive vias 116b are formed using a deposition process (e.g., a physical vapor deposition process or an atomic layer deposition process) or a plating process and a planarization process (e.g., a chemical mechanical polishing process), in accordance with some embodiments.

As shown in FIGS. 1A and 1A-1, a conductive layer 120 is formed over the substrate 110, in accordance with some embodiments. The conductive layer 120 is electrically connected to the interconnect structure 116, in accordance with some embodiments.

The conductive layer 120 is physically connected to the interconnect structure 116, in accordance with some embodiments. As shown in FIG. 1A, the conductive layer 120 has a straight line shape, in accordance with some embodiments.

As shown in FIGS. 1A and 1A-1, the conductive layer 120 has a trench 121, in accordance with some embodiments. The conductive layer 120 is divided into a main portion 122 and an island portion 124 by the trench 121, in accordance with some embodiments. The main portion 122 is electrically insulated from the island portion 124, in accordance with some embodiments.

The conductive layer 120 is made of a conductive material, such as metal nitride (e.g., titanium nitride), in accordance with some embodiments. The conductive layer 120 is formed using a deposition process (e.g., a physical vapor deposition process or an atomic layer deposition process), a photolithography process, and an etching process (e.g., a dry etching process), in accordance with some embodiments.

In some other embodiments, the conductive layer 120 is made of a conductive material, such as metal (e.g., titanium, copper, nickel, aluminum, gold, silver, tin, or tungsten) or alloys thereof. The conductive layer 120 is formed using a plating process, a photolithography process, and an etching process (e.g., a dry etching process), in accordance with some embodiments.

FIG. 1B-1 is a top view of the semiconductor device structure of FIG. 1B, in accordance with some embodiments. FIG. 1B is a cross-sectional view illustrating the semiconductor device structure along a sectional line I-I’ in FIG. 1B-1, in accordance with some embodiments.

As shown in FIGS. 1B and 1B-1, a dielectric layer 130 is formed over the conductive layer 120 and the substrate 110, in accordance with some embodiments. The dielectric layer 130 has trenches 132, in accordance with some embodiments.

The trenches 132 pass through the dielectric layer 130, in accordance with some embodiments. The trenches 132 expose a portion of the main portion 122 of the conductive layer 120, in accordance with some embodiments.

The dielectric layer 130 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 130 includes a low-k material or a porous dielectric material having a k-value which is lower than that of silicon oxide, or lower than about 3.0 or about 2.5, in accordance with some embodiments.

The dielectric layer 130 is formed using a deposition process, a photolithography process, and an etching process (e.g., a dry etching process), in accordance with some embodiments. The deposition process includes a chemical vapor deposition (CVD) process, such as a low-pressure CVD process, a plasma-enhanced CVD process, or a high-density plasma CVD process, an atomic layer deposition process, a physical vapor deposition process, or another suitable process, in accordance with some embodiments.

As shown in FIGS. 1B and 1B-1, a conductive layer 140 is formed over the dielectric layer 130 and in the trenches 132, in accordance with some embodiments. The conductive layer 140 has a trench 141, in accordance with some embodiments. The conductive layer 140 has a thickness T140 ranging from about 200 Å to 700 Å, in accordance with some embodiments.

The conductive layer 140 is divided into an electrode 142 and an island portion 144 by the trench 141, in accordance with some embodiments. The electrode 142 is electrically insulated from the island portion 144, in accordance with some embodiments. In some embodiments, bottom parts of the electrode 142 are connected to the main portion 122 of the conductive layer 120.

The electrode 142 is electrically connected to the main portion 122 of the conductive layer 120, in accordance with some embodiments. The electrode 142 in the trench 132 of the dielectric layer 130 has a U-like shape, in accordance with some embodiments. The electrode 142 passes through the dielectric layer 130, in accordance with some embodiments.

The conductive layer 140 is made of a conductive material, such as metal nitride (e.g., titanium nitride), in accordance with some embodiments. The conductive layer 140 is formed using a deposition process (e.g., a physical vapor deposition process or an atomic layer deposition process), a photolithography process, and an etching process (e.g., a dry etching process), in accordance with some embodiments.

In some other embodiments, the conductive layer 140 is made of a conductive material, such as metal (e.g., titanium, copper, nickel, aluminum, gold, silver, tin, or tungsten) or alloys thereof. The conductive layer 140 is formed using a plating process, a photolithography process, and an etching process (e.g., a dry etching process), in accordance with some embodiments.

FIG. 1C-1 is a top view of the semiconductor device structure of FIG. 1C, in accordance with some embodiments. FIG. 1C is a cross-sectional view illustrating the semiconductor device structure along a sectional line I-I’ in FIG. 1C-1, in accordance with some embodiments.

As shown in FIGS. 1C and 1C-1, a dielectric film 150 is formed over the conductive layer 140, in accordance with some embodiments. The dielectric film 150 conformally covers the conductive layer 140 and the dielectric layer 130, in accordance with some embodiments. The dielectric film 150 has a thickness T150 ranging from about 40 Å to 80 Å, in accordance with some embodiments.

The dielectric film 150 is made of a high-k material (e.g., HfO₂, ZrO₂, HfZrO₂, or Al₂O₃), an oxide-containing material (e.g., silicon oxide or tetraethyl orthosilicate (TEOS) oxide), a nitride-containing material (e.g., silicon nitride), an oxynitride-containing material (e.g., silicon oxynitride), a carbide-containing material (e.g., silicon carbide), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

The dielectric film 150 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIGS. 1C and 1C-1, a conductive layer 160 is formed over the dielectric film 150 and in the trenches 132, in accordance with some embodiments. The conductive layer 160 has a trench 161, in accordance with some embodiments.

The conductive layer 160 is divided into an electrode 162 and an island portion 164 by the trench 161, in accordance with some embodiments. The electrode 162 is electrically insulated from the island portion 164, in accordance with some embodiments.

The dielectric film 150 electrically insulates the electrode 142 from the electrode 162, in accordance with some embodiments. As shown in FIG. 1C, the electrode 162 has a T-like shape, in accordance with some embodiments. The conductive layer 160 has a thickness T160 ranging from about 200 Å to 700 Å, in accordance with some embodiments.

The conductive layer 160 is made of a conductive material, such as metal nitride (e.g., titanium nitride), in accordance with some embodiments. The conductive layer 160 is formed using a deposition process (e.g., a physical vapor deposition process or an atomic layer deposition process), a photolithography process, and an etching process (e.g., a dry etching process), in accordance with some embodiments.

In some other embodiments, the conductive layer 160 is made of a conductive material, such as metal (e.g., titanium, copper, nickel, aluminum, gold, silver, tin, or tungsten) or alloys thereof. The conductive layer 160 is formed using a plating process, a photolithography process, and an etching process (e.g., a dry etching process), in accordance with some embodiments.

FIG. 1D-1 is a top view of the semiconductor device structure of FIG. 1D, in accordance with some embodiments. FIG. 1D is a cross-sectional view illustrating the semiconductor device structure along a sectional line I-I’ in FIG. 1D-1, in accordance with some embodiments.

As shown in FIGS. 1D and 1D-1, a dielectric film 170 is formed over the conductive layer 160, in accordance with some embodiments. The dielectric film 170 conformally covers the conductive layer 160, in accordance with some embodiments. The dielectric film 170 has a thickness T170 ranging from about 40 Å to 80 Å, in accordance with some embodiments.

The dielectric film 170 is made of a high-k material (e.g., HfO₂, ZrO₂, HfZrO₂, or Al₂O₃), an oxide-containing material (e.g., silicon oxide or tetraethyl orthosilicate (TEOS) oxide), a nitride-containing material (e.g., silicon nitride), an oxynitride-containing material (e.g., silicon oxynitride), a carbide-containing material (e.g., silicon carbide), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

The dielectric film 170 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIGS. 1D and 1D-1, a conductive layer 180 is formed over the dielectric film 170, in accordance with some embodiments. The dielectric film 170 electrically insulates the conductive layer 180 from the conductive layer 160, in accordance with some embodiments. The conductive layer 180 is made of a conductive material, such as metal nitride (e.g., titanium nitride), in accordance with some embodiments.

The conductive layer 180 is formed using a deposition process (e.g., a physical vapor deposition process or an atomic layer deposition process), a photolithography process, and an etching process (e.g., a dry etching process), in accordance with some embodiments.

In some other embodiments, the conductive layer 180 is made of a conductive material, such as metal (e.g., titanium, copper, nickel, aluminum, gold, silver, tin, or tungsten) or alloys thereof. The conductive layer 180 is formed using a plating process, a photolithography process, and an etching process (e.g., a dry etching process), in accordance with some embodiments.

As shown in FIGS. 1D and 1D-1, a mask layer M1 is formed over the conductive layer 180, in accordance with some embodiments. The mask layer M1 is over the trenches 132 of the dielectric layer 130, in accordance with some embodiments. The mask layer M1 is made of a polymer material such as a photoresist material, in accordance with some embodiments.

FIG. 1E-1 is a top view of the semiconductor device structure of FIG. 1E, in accordance with some embodiments. FIG. 1E is a cross-sectional view illustrating the semiconductor device structure along a sectional line I-I’ in FIG. 1E-1, in accordance with some embodiments.

As shown in FIGS. 1E and 1E-1, the portions of the conductive layer 180 exposed by the mask layer M1 are removed, in accordance with some embodiments. As shown in FIGS. 1E and 1E-1, the mask layer M1 is also removed, in accordance with some embodiments.

After the removal process is performed, the portions of the conductive layer 180 remaining over the dielectric film 170 form electrodes 182, in accordance with some embodiments. The electrodes 182 are over the electrode 162, in accordance with some embodiments.

The electrodes 182 are over the trenches 132 of the dielectric layer 130, in accordance with some embodiments. The electrode 182 has a thickness T182 ranging from about 200 Å to 700 Å, in accordance with some embodiments. The removal process includes an etching process such as a dry etching process, in accordance with some embodiments.

FIG. 1F-1 is a top view of the semiconductor device structure of FIG. 1F, in accordance with some embodiments. FIG. 1F is a cross-sectional view illustrating the semiconductor device structure along a sectional line I-I’ in FIG. 1F-1, in accordance with some embodiments.

As shown in FIGS. 1F and 1F-1, a dielectric film 190 is formed over the dielectric film 170 and the electrodes 182, in accordance with some embodiments. The dielectric film 190 conformally covers the dielectric film 170 and the electrodes 182, in accordance with some embodiments. The dielectric film 190 has a thickness T190 ranging from about 40 Å to 80 Å, in accordance with some embodiments.

The dielectric film 190 is made of a high-k material (e.g., HfO₂, ZrO₂, HfZrO₂, or Al₂O₃), an oxide-containing material (e.g., silicon oxide or tetraethyl orthosilicate (TEOS) oxide), a nitride-containing material (e.g., silicon nitride), an oxynitride-containing material (e.g., silicon oxynitride), a carbide-containing material (e.g., silicon carbide), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

The dielectric film 190 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIGS. 1F and 1F-1, a conductive layer 210 is formed over the dielectric film 190, in accordance with some embodiments. The conductive layer 210 has a trench 211, in accordance with some embodiments. The conductive layer 210 is divided into an electrode 212 and an island portion 214 by the trench 211, in accordance with some embodiments.

The electrode 212 is electrically insulated from the island portion 214, in accordance with some embodiments. The dielectric film 190 electrically insulates the electrodes 182 from the electrode 212, in accordance with some embodiments. As shown in FIG. 1F, the electrode 212 has a reversed U-like shape, in accordance with some embodiments.

The electrode 212 overlaps the electrodes 142, 162, and 182, in accordance with some embodiments. The electrodes 142, 162, 182, and 212 and the dielectric films 150, 170, and 190 together form a capacitor 10, in accordance with some embodiments. The conductive layer 210 has a thickness T210 ranging from about 200 Å to 700 Å, in accordance with some embodiments.

The conductive layer 210 is made of a conductive material, such as metal nitride (e.g., titanium nitride), in accordance with some embodiments. The conductive layer 210 is formed using a deposition process (e.g., a physical vapor deposition process or an atomic layer deposition process), a photolithography process, and an etching process (e.g., a dry etching process), in accordance with some embodiments.

In some other embodiments, the conductive layer 210 is made of a conductive material, such as metal (e.g., titanium, copper, nickel, aluminum, gold, silver, tin, or tungsten) or alloys thereof.

The conductive layer 210 is formed using a plating process, a photolithography process, and an etching process (e.g., a dry etching process), in accordance with some embodiments.

As shown in FIG. 1G, a dielectric layer 220 is formed over the conductive layer 210, in accordance with some embodiments. In some embodiments, the top surface 222 of the dielectric layer 220 is substantially level with the top surface 212a of the electrode 212.

The dielectric layer 220 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 220 includes a low-k material or a porous dielectric material having a k-value which is lower than that of silicon oxide, or lower than about 3.0 or about 2.5, in accordance with some embodiments.

The dielectric layer 220 is formed using a deposition process and a planarization process (e.g., a chemical mechanical polishing process), in accordance with some embodiments.

The deposition process includes a chemical vapor deposition (CVD) process, such as a low-pressure CVD process, a plasma-enhanced CVD process, or a high-density plasma CVD process, an atomic layer deposition process, a physical vapor deposition process, or another suitable process, in accordance with some embodiments.

FIG. 1H-1 is a top view of the semiconductor device structure of FIG. 1H, in accordance with some embodiments. FIG. 1H is a cross-sectional view illustrating the semiconductor device structure along a sectional line I-I’ in FIG. 1H-1, in accordance with some embodiments.

As shown in FIGS. 1H and 1H-1, a dielectric layer 230 is formed over the conductive layer 290 and the dielectric layer 220, in accordance with some embodiments. The dielectric layer 230 has trenches 232, in accordance with some embodiments.

The trenches 232 pass through the dielectric layer 230, in accordance with some embodiments. The trenches 232 expose a portion of the electrode 292, in accordance with some embodiments.

The dielectric layer 230 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 230 includes a low-k material or a porous dielectric material having a k-value which is lower than that of silicon oxide, or lower than about 3.0 or about 2.5, in accordance with some embodiments.

The dielectric layer 230 is formed using a deposition process, a photolithography process, and an etching process (e.g., a dry etching process), in accordance with some embodiments. The deposition process includes a chemical vapor deposition (CVD) process, such as a low-pressure CVD process, a plasma-enhanced CVD process, or a high-density plasma CVD process, an atomic layer deposition process, a physical vapor deposition process, or another suitable process, in accordance with some embodiments.

As shown in FIGS. 1H and 1H-1, a conductive layer 240 is formed over the dielectric layer 230 and in the trenches 232, in accordance with some embodiments. The conductive layer 240 has a trench 241, in accordance with some embodiments. The conductive layer 240 has a thickness T240 ranging from about 200 Å to 700 Å, in accordance with some embodiments.

The conductive layer 240 is divided into an electrode 242 and an island portion 244 by the trench 241, in accordance with some embodiments. The electrode 242 is electrically insulated from the island portion 244, in accordance with some embodiments. In some embodiments, bottom parts of the electrode 242 are connected to the electrode 292.

The electrode 242 is electrically connected to the electrode 292, in accordance with some embodiments. The electrode 242 in the trench 232 of the dielectric layer 230 has a U-like shape, in accordance with some embodiments. The electrode 242 passes through the dielectric layer 230, in accordance with some embodiments.

The conductive layer 240 is made of a conductive material, such as metal nitride (e.g., titanium nitride), in accordance with some embodiments. The conductive layer 240 is formed using a deposition process (e.g., a physical vapor deposition process or an atomic layer deposition process), a photolithography process, and an etching process (e.g., a dry etching process), in accordance with some embodiments.

In some other embodiments, the conductive layer 240 is made of a conductive material, such as metal (e.g., titanium, copper, nickel, aluminum, gold, silver, tin, or tungsten) or alloys thereof. The conductive layer 240 is formed using a plating process, a photolithography process, and an etching process (e.g., a dry etching process), in accordance with some embodiments.

FIG. 1I-1 is a top view of the semiconductor device structure of FIG. 1I, in accordance with some embodiments. FIG. 1I is a cross-sectional view illustrating the semiconductor device structure along a sectional line I-I’ in FIG. 1I-1, in accordance with some embodiments.

As shown in FIGS. 1I and 1I-1, a dielectric film 250 is formed over the conductive layer 240, in accordance with some embodiments. The dielectric film 250 conformally covers the conductive layer 240 and the dielectric layer 230, in accordance with some embodiments. The dielectric film 250 has a thickness T250 ranging from about 40 Å to 80 Å, in accordance with some embodiments.

The dielectric film 250 is made of a high-k material (e.g., HfO₂, ZrO₂, HfZrO₂, or Al₂O₃), an oxide-containing material (e.g., silicon oxide or tetraethyl orthosilicate (TEOS) oxide), a nitride-containing material (e.g., silicon nitride), an oxynitride-containing material (e.g., silicon oxynitride), a carbide-containing material (e.g., silicon carbide), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

The dielectric film 250 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIGS. 1I and 1I-1, a conductive layer 260 is formed over the dielectric film 250 and in the trenches 232, in accordance with some embodiments. The conductive layer 260 has a trench 261, in accordance with some embodiments.

The conductive layer 260 is divided into an electrode 262 and an island portion 264 by the trench 261, in accordance with some embodiments. The electrode 262 is electrically insulated from the island portion 264, in accordance with some embodiments.

The dielectric film 250 electrically insulates the electrode 242 from the electrode 262, in accordance with some embodiments. As shown in FIG. 1I, the electrode 262 has a T-like shape, in accordance with some embodiments. The conductive layer 260 has a thickness T260 ranging from about 200 Å to 700 Å, in accordance with some embodiments.

The conductive layer 260 is made of a conductive material, such as metal nitride (e.g., titanium nitride), in accordance with some embodiments. The conductive layer 260 is formed using a deposition process (e.g., a physical vapor deposition process or an atomic layer deposition process), a photolithography process, and an etching process (e.g., a dry etching process), in accordance with some embodiments.

In some other embodiments, the conductive layer 260 is made of a conductive material, such as metal (e.g., titanium, copper, nickel, aluminum, gold, silver, tin, or tungsten) or alloys thereof. The conductive layer 260 is formed using a plating process, a photolithography process, and an etching process (e.g., a dry etching process), in accordance with some embodiments.

FIG. 1J-1 is a top view of the semiconductor device structure of FIG. 1J, in accordance with some embodiments. FIG. 1J is a cross-sectional view illustrating the semiconductor device structure along a sectional line I-I’ in FIG. 1J-1, in accordance with some embodiments.

As shown in FIGS. 1J and 1J-1, a conductive layer 270 is formed over the dielectric film 250 and the conductive layer 260, in accordance with some embodiments. The dielectric film 250 electrically insulates the conductive layer 270 from the conductive layer 240, in accordance with some embodiments. The conductive layer 270 is made of a conductive material, such as metal nitride (e.g., titanium nitride), in accordance with some embodiments.

The conductive layer 270 is formed using a deposition process (e.g., a physical vapor deposition process or an atomic layer deposition process), a photolithography process, and an etching process (e.g., a dry etching process), in accordance with some embodiments.

In some other embodiments, the conductive layer 270 is made of a conductive material, such as metal (e.g., titanium, copper, nickel, aluminum, gold, silver, tin, or tungsten) or alloys thereof.

The conductive layer 270 is formed using a plating process, a photolithography process, and an etching process (e.g., a dry etching process), in accordance with some embodiments.

As shown in FIGS. 1J and 1J-1, a mask layer M2 is formed over the conductive layer 270, in accordance with some embodiments. The mask layer M2 is over the trenches 232 of the dielectric layer 230, in accordance with some embodiments. The mask layer M2 is made of a polymer material such as a photoresist material, in accordance with some embodiments.

FIG. 1K-1 is a top view of the semiconductor device structure of FIG. 1K, in accordance with some embodiments. FIG. 1K is a cross-sectional view illustrating the semiconductor device structure along a sectional line I-I’ in FIG. 1K-1, in accordance with some embodiments.

As shown in FIGS. 1K and 1K-1, the portions of the conductive layer 270 exposed by the mask layer M2 are removed, in accordance with some embodiments. As shown in FIGS. 1K and 1K-1, the mask layer M2 is also removed, in accordance with some embodiments.

After the removal process is performed, the portions of the conductive layer 270 remaining over the conductive layer 260 form electrodes 272, in accordance with some embodiments. The electrodes 272 are over the electrode 262, in accordance with some embodiments.

The electrodes 272 are over the trenches 232 of the dielectric layer 230, in accordance with some embodiments. The electrode 272 has a thickness T272 ranging from about 200 Å to 700 Å, in accordance with some embodiments. The removal process includes an etching process such as a dry etching process, in accordance with some embodiments.

FIG. 1L-1 is a top view of the semiconductor device structure of FIG. 1L, in accordance with some embodiments. FIG. 1L is a cross-sectional view illustrating the semiconductor device structure along a sectional line I-I’ in FIG. 1L-1, in accordance with some embodiments.

As shown in FIGS. 1L and 1L-1, a dielectric film 280 is formed over the dielectric film 250 and the conductive layer 260, in accordance with some embodiments. The dielectric film 280 conformally covers the dielectric film 250 and the conductive layer 260, in accordance with some embodiments. The dielectric film 280 has a thickness T280 ranging from about 40 Å to 80 Å, in accordance with some embodiments.

The dielectric film 280 is made of a high-k material (e.g., HfO₂, ZrO₂, HfZrO₂, or Al₂O₃), an oxide-containing material (e.g., silicon oxide or tetraethyl orthosilicate (TEOS) oxide), a nitride-containing material (e.g., silicon nitride), an oxynitride-containing material (e.g., silicon oxynitride), a carbide-containing material (e.g., silicon carbide), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

The dielectric film 280 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIGS. 1L and 1L-1, a conductive layer 290 is formed over the dielectric film 280, in accordance with some embodiments. The conductive layer 290 has a trench 291, in accordance with some embodiments. The conductive layer 290 is divided into an electrode 292 and an island portion 294 by the trench 291, in accordance with some embodiments.

The electrode 292 is electrically insulated from the island portion 294, in accordance with some embodiments. The dielectric film 280 electrically insulates the electrodes 272 from the electrode 292, in accordance with some embodiments. As shown in FIG. 1L, the electrode 292 has a reversed U-like shape, in accordance with some embodiments.

The electrode 292 overlaps the electrodes 242, 262, and 272, in accordance with some embodiments. The electrodes 242, 262, 272, and 292 and the dielectric films 250 and 280 together form a capacitor 20, in accordance with some embodiments. The conductive layer 290 has a thickness T210 ranging from about 200 Å to 700 Å, in accordance with some embodiments.

The conductive layer 290 is made of a conductive material, such as metal nitride (e.g., titanium nitride), in accordance with some embodiments. The conductive layer 290 is formed using a deposition process (e.g., a physical vapor deposition process or an atomic layer deposition process), a photolithography process, and an etching process (e.g., a dry etching process), in accordance with some embodiments.

In some other embodiments, the conductive layer 290 is made of a conductive material, such as metal (e.g., titanium, copper, nickel, aluminum, gold, silver, tin, or tungsten) or alloys thereof.

The conductive layer 290 is formed using a plating process, a photolithography process, and an etching process (e.g., a dry etching process), in accordance with some embodiments.

As shown in FIGS. 1L and 1L-1, a conductive layer 310 is formed over the conductive layer 290, in accordance with some embodiments. The conductive layer 310 has a trench 311, in accordance with some embodiments. The conductive layer 310 is divided into a main portion 312 and an island portion 314 by the trench 311, in accordance with some embodiments.

The electrode 312 is electrically insulated from the island portion 314, in accordance with some embodiments. The conductive layer 310 is made of a conductive material, such as metal nitride (e.g., titanium nitride), in accordance with some embodiments.

The conductive layer 310 is formed using a deposition process (e.g., a physical vapor deposition process or an atomic layer deposition process), a photolithography process, and an etching process (e.g., a dry etching process), in accordance with some embodiments.

In some other embodiments, the conductive layer 310 is made of a conductive material, such as metal (e.g., titanium, copper, nickel, aluminum, gold, silver, tin, or tungsten) or alloys thereof.

The conductive layer 310 is formed using a plating process, a photolithography process, and an etching process (e.g., a dry etching process), in accordance with some embodiments.

FIG. 1M-1 is a top view of the semiconductor device structure of FIG. 1M, in accordance with some embodiments. FIG. 1M is a cross-sectional view illustrating the semiconductor device structure along a sectional line I-I’ in FIG. 1M-1, in accordance with some embodiments. It should be noted that, for the sake of simplicity, FIG. 1M-1 omits depicting the dielectric layer 350, in accordance with some embodiments.

As shown in FIGS. 1M and 1M-1, a dielectric layer 320 is formed over the conductive layer 310, in accordance with some embodiments. The dielectric layer 320 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 320 includes a low-k material or a porous dielectric material having a k-value which is lower than that of silicon oxide, or lower than about 3.0 or about 2.5, in accordance with some embodiments.

The dielectric layer 320 is formed using a deposition process and a planarization process (e.g., a chemical mechanical polishing process), in accordance with some embodiments.

The deposition process includes a chemical vapor deposition (CVD) process, such as a low-pressure CVD process, a plasma-enhanced CVD process, or a high-density plasma CVD process, an atomic layer deposition process, a physical vapor deposition process, or another suitable process, in accordance with some embodiments.

FIG. 1M-1 is a top view of the semiconductor device structure of FIG. 1M, in accordance with some embodiments. As shown in FIGS. 1M and 1M-1, portions of the conductive layer 120, the dielectric layer 130, the conductive layer 140, the dielectric film 150, the conductive layer 160, the dielectric film 170, the dielectric film 190, the conductive layer 210, the dielectric layer 220, the dielectric layer 230, the conductive layer 240, the dielectric film 250, the conductive layer 260, the dielectric film 280, the conductive layer 290, the conductive layer 310, and the dielectric layer 320 are removed to form through holes TH1 and TH2, in accordance with some embodiments.

The through holes TH1 and TH2 pass through the conductive layer 120, the dielectric layer 130, the conductive layer 140, the dielectric film 150, the conductive layer 160, the dielectric film 170, the dielectric film 190, the conductive layer 210, the dielectric layer 220, the dielectric layer 230, the conductive layer 240, the dielectric film 250, the conductive layer 260, the dielectric film 280, the conductive layer 290, the conductive layer 310, and the dielectric layer 320 are removed to form through holes TH1 and TH2, in accordance with some embodiments.

The through hole TH1 exposes a portion of the metal line 116a1 of the (topmost) wiring layer 116a, in accordance with some embodiments. The through hole TH2 exposes a portion of the metal line 116a2 of the (topmost) wiring layer 116a, in accordance with some embodiments.

The removal process includes a photolithography process and an etching process (e.g., a dry etching process), in accordance with some embodiments.

As shown in FIGS. 1M and 1M-1, conductive plugs 332 and 334 are formed in the through holes TH1 and TH2 respectively, and conductive lines 342 and 344 are formed over the conductive plugs 332 and 334 respectively, in accordance with some embodiments. The conductive line 342 is connected to the conductive plug 332, in accordance with some embodiments. The conductive line 344 is connected to the conductive plug 334, in accordance with some embodiments.

The conductive plug 332 passes through the island portion 124 of the conductive layer 120, the dielectric layer 130, the island portion 144 of the conductive layer 140, the dielectric film 150, the electrode 162 of the conductive layer 160, the dielectric film 170, the dielectric film 190, the island portion 214 of the conductive layer 210, the dielectric layer 220, the dielectric layer 230, the island portion 244 of the conductive layer 240, the dielectric film 250, the electrode 262 of the conductive layer 260, the dielectric film 280, the island portion 294 of the conductive layer 290, the island portion 314 of the conductive layer 310, and the dielectric layer 320, in accordance with some embodiments.

The conductive plug 332 is in direct contact with the island portion 124 of the conductive layer 120, the dielectric layer 130, the island portion 144 of the conductive layer 140, the dielectric film 150, the electrode 162 of the conductive layer 160, the dielectric film 170, the dielectric film 190, the island portion 214 of the conductive layer 210, the dielectric layer 220, the dielectric layer 230, the island portion 244 of the conductive layer 240, the dielectric film 250, the electrode 262 of the conductive layer 260, the dielectric film 280, the island portion 294 of the conductive layer 290, the island portion 314 of the conductive layer 310, and the dielectric layer 320, in accordance with some embodiments.

The conductive plug 332 is electrically connected to the electrode 162 of the conductive layer 160 and the electrode 262 of the conductive layer 260, in accordance with some embodiments.

The conductive plug 332 is further electrically connected to the island portion 124 of the conductive layer 120, the island portion 144 of the conductive layer 140, the island portion 214 of the conductive layer 210, the island portion 244 of the conductive layer 240, the island portion 294 of the conductive layer 290, and the island portion 314 of the conductive layer 310, in accordance with some embodiments.

The conductive plug 334 passes through the main portion 122 of the conductive layer 120, the dielectric layer 130, the electrode 142 of the conductive layer 140, the dielectric film 150, the island portion 164 of the conductive layer 160, the dielectric film 170, the dielectric film 190, the electrode 212 of the conductive layer 210, the dielectric layer 220, the dielectric layer 230, the electrode 242 of the conductive layer 240, the dielectric film 250, the island portion 264 of the conductive layer 260, the dielectric film 280, the electrode 292 of the conductive layer 290, the main portion 312 of the conductive layer 310, and the dielectric layer 320, in accordance with some embodiments.

The conductive plug 334 is in direct contact with the main portion 122 of the conductive layer 120, the dielectric layer 130, the electrode 142 of the conductive layer 140, the dielectric film 150, the island portion 164 of the conductive layer 160, the dielectric film 170, the dielectric film 190, the electrode 212 of the conductive layer 210, the dielectric layer 220, the dielectric layer 230, the electrode 242 of the conductive layer 240, the dielectric film 250, the island portion 264 of the conductive layer 260, the dielectric film 280, the electrode 292 of the conductive layer 290, the main portion 312 of the conductive layer 310, and the dielectric layer 320, in accordance with some embodiments.

The conductive plug 334 is electrically connected to the main portion 122 of the conductive layer 120, the electrode 142 of the conductive layer 140, the electrode 212 of the conductive layer 210, the electrode 242 of the conductive layer 240, the electrode 292 of the conductive layer 290, and the main portion 312 of the conductive layer 310, in accordance with some embodiments.

The conductive plug 334 is further electrically connected to the island portion 164 of the conductive layer 160 and the island portion 264 of the conductive layer 260, in accordance with some embodiments.

As shown in FIG. 1M, a portion 122a of the main portion 122 of the conductive layer 120 is between the electrode 162 and the conductive plug 334. As shown in FIG. 1M, the portion 122a of the main portion 122 has a straight line shape, in accordance with some embodiments. In some embodiments, the entire conductive layer 120 has a straight line shape. The portion 122a is between the conductive plugs 332 and 334, in accordance with some embodiments.

As shown in FIG. 1M, a portion 142a of the electrode 142 is between the electrode 162 and the conductive plug 334, in accordance with some embodiments. As shown in FIG. 1M, the portion 142a of the electrode 142 has an L-like shape, in accordance with some embodiments.

The capacitor 10 is electrically connected to the conductive plug 334 through the portion 122a of the conductive layer 120 and the portion 142a of the electrode 142, in accordance with some embodiments.

Since the portion 122a of the conductive layer 120 with a straight line shape is shorter than the portion 142a of the electrode 142 with a an L-like shape, the conductive layer 120 can shorten the conductive path between the capacitor 10 and the conductive plug 334, in accordance with some embodiments. Therefore, the performance of the semiconductor device structure with the conductive layer 120 is improved, in accordance with some embodiments.

As shown in FIG. 1M, a portion 134 of the dielectric layer 130 is surrounded by the portion 122a of the conductive layer 120, the portion 142a of the electrode 142, and the conductive plug 334, in accordance with some embodiments.

In some embodiments, the conductive plugs 332 and 334 and the conductive lines 342 and 344 are made of a conductive material, such as metal (e.g., titanium, copper, nickel, aluminum, gold, silver, tin, or tungsten) or alloys thereof.

The formation of the conductive plugs 332 and 334 and the conductive lines 342 and 344 includes: forming a seed layer over the dielectric layer 320 and in the through holes TH1 and TH2; forming a mask layer over the seed layer, wherein the mask layer has openings exposing portions of the seed layer; plating a conductive layer over the exposed portions of the seed layer and in the openings of the mask layer; and removing the mask layer and portions of the seed layer under the mask layer, in accordance with some embodiments.

As shown in FIGS. 1M and 1M-1, a dielectric layer 350 is formed over the conductive lines 342 and 344 and the dielectric layer 320, in accordance with some embodiments. In this step, a semiconductor device structure 100 is substantially formed, in accordance with some embodiments.

The dielectric layer 350 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 350 includes a low-k material or a porous dielectric material having a k-value which is lower than that of silicon oxide, or lower than about 3.0 or about 2.5, in accordance with some embodiments.

The dielectric layer 350 is formed using a deposition process and a planarization process (e.g., a chemical mechanical polishing process), in accordance with some embodiments.

The deposition process includes a chemical vapor deposition (CVD) process, such as a low-pressure CVD process, a plasma-enhanced CVD process, or a high-density plasma CVD process, an atomic layer deposition process, a physical vapor deposition process, or another suitable process, in accordance with some embodiments.

As shown in FIG. 1M, the electrode 142 has sidewalls 142s1 and 142s2, in accordance with some embodiments. The sidewalls 142s1 and 142s2 face the conductive plug 332, in accordance with some embodiments. In some embodiments, a distance D142s between the sidewalls 142s1 and 142s2 ranges from about 0.2 μm to about 0.8 μm.

The trench 132 has a width W132 ranging from about 0.1 μm to about 0.4 μm, in accordance with some embodiments. The trench 232 has a width W232 ranging from about 0.1 μm to about 0.4 μm, in accordance with some embodiments.

The electrode 182 has a width W182 ranging from about 0.1 μm to about 0.4 μm, in accordance with some embodiments. The electrode 272 has a width W272 ranging from about 0.1 μm to about 0.4 μm, in accordance with some embodiments.

The distance D132 between the trenches 132 ranges from about 0.1 μm to about 0.4 μm, in accordance with some embodiments. The distance D232 between the trenches 232 ranges from about 0.1 μm to about 0.4 μm, in accordance with some embodiments.

The depth DE132 of the trench 132 ranges from about 0.2 μm to about 0.8 μm, in accordance with some embodiments. The depth DE232 of the trench 232 ranges from about 0.2 μm to about 0.8 μm, in accordance with some embodiments.

The angle θ182 between the sidewall 182s of the electrode 182 and the top surface 172 of the dielectric film 170 ranges from about 90˚ to about 105˚, in accordance with some embodiments. The angle θ272 between the sidewall 272s of the electrode 272 and the top surface 262a of the electrode 262 ranges from about 90° to about 105°, in accordance with some embodiments.

The thickness T10 of the capacitor 10 ranges from about 0.4 μm to about 1.6 μm, in accordance with some embodiments. The thickness T20 of the capacitor 20 ranges from about 0.4 μm to about 1.6 μm, in accordance with some embodiments.

The angle θ132 between the inner wall 132a of the trench 132 and the top surface 122b of the electrode 122 ranges from about 75° to about 90°, in accordance with some embodiments. The angle θ232 between the inner wall 232a of the trench 232 and the top surface 222 of the dielectric layer 220 ranges from about 75° to about 90°, in accordance with some embodiments.

The conductive plug 332 has a width W332 ranging from about 0.8 μm to about 2.7 μm, in accordance with some embodiments. The conductive plug 334 has a width W334 ranging from about 0.8 μm to about 2.7 μm, in accordance with some embodiments.

The conductive line 342 has a width W342 ranging from about 1.2 μm to about 35 μm, in accordance with some embodiments. The metal line 116a1 has a width W116a1 ranging from about 1.2 μm to about 20 μm, in accordance with some embodiments.

The distance D332a between the sidewalls of the conductive plug 332 and the conductive line 342 ranges from about 0.2 μm to about 0.4 μm, in accordance with some embodiments. The distance D332b between the sidewalls of the conductive plug 332 and the metal line 116a1 ranges from about 0.2 μm to about 0.4 μm, in accordance with some embodiments.

The width W1 of the conductive layer 140, 160, 210, 240, 260, or 290 ranges from about 1 μm to about 300 μm, in accordance with some embodiments. The width W2 of the trench 241, 291, or 311 ranges from about 2.5 μm to about 5 μm, in accordance with some embodiments.

The distance D1 between the electrode 182 or 272 and the trench 241, 291, or 311 ranges from about 0.1 μm to about 0.5 μm, in accordance with some embodiments. The distance D2 between the trench 132 or 232 and the trench 241, 291, or 311 ranges from about 0.1 μm to about 0.5 μm, in accordance with some embodiments.

The distance D3 between the electrode 182 or 272 and the edge of the conductive layer 140, 160, 210, 240, 260, or 290 ranges from about 0.1 μm to about 0.5 μm, in accordance with some embodiments. The distance D4 between the trench 132 or 232 and the edge of the conductive layer 140, 160, 210, 240, 260, or 290 ranges from about 0.1 μm to about 0.5 μm, in accordance with some embodiments.

It should be noted that, for the sake of simplicity, FIG. 1M-1 shows two electrodes 182, two trenches 132, two electrodes 272, and two trenches 232 for illustration, but does not limit the application thereto. For example, the number of electrodes 182, trenches 132, electrodes 272, or trenches 232 may be greater than two (as shown in FIGS. 2-9).

FIG. 2 is a top view of a semiconductor device structure 200, in accordance with some embodiments. It should be noted that, for the sake of simplicity, FIG. 2 omits depicting the dielectric layer 320, the conductive plugs 332 and 334, the conductive lines 342 and 344, and the dielectric layer 350 of the semiconductor device structure 100, in accordance with some embodiments.

As shown in FIG. 2, the semiconductor device structure 200 is similar to the semiconductor device structure 100 of FIG. 1M-1, except that the semiconductor device structure 200 has more than two electrodes 182, more than two trenches 132, more than two electrodes 272, and more than two trenches 232, and the electrodes 182, the trenches 132, the electrodes 272, and the trenches 232 have a square shape, in accordance with some embodiments.

The electrodes 182 are arranged in a rectangular array, in accordance with some embodiments. The trenches 132 are arranged in a rectangular array, in accordance with some embodiments. The electrodes 272 are arranged in a rectangular array, in accordance with some embodiments. The trenches 232 are arranged in a rectangular array, in accordance with some embodiments.

In some embodiments, the width W182 of the electrode 182 is less than the width W132 of the trenches 132. In some embodiments, the width W272 of the electrode 272 is less than the width W232 of the trenches 232.

In some other embodiments (not shown), the width W182 of the electrode 182 is the same as or greater than the width W132 of the trenches 132. In some other embodiments (not shown), the width W272 of the electrode 272 is the same as or greater than the width W232 of the trenches 232.

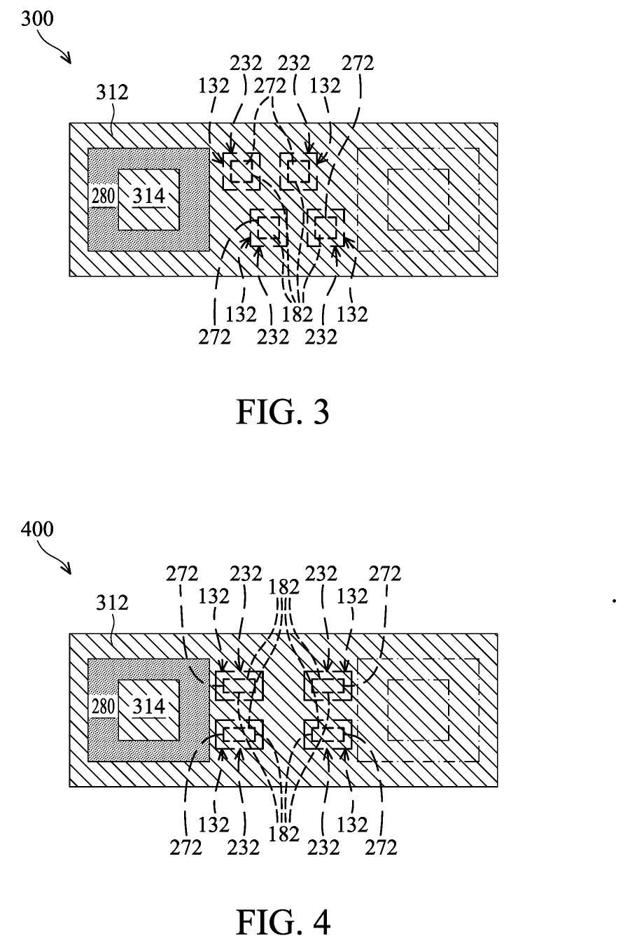

FIG. 3 is a top view of a semiconductor device structure 300, in accordance with some embodiments. It should be noted that, for the sake of simplicity, FIG. 3 omits depicting the dielectric layer 320, the conductive plugs 332 and 334, the conductive lines 342 and 344, and the dielectric layer 350 of the semiconductor device structure 100, in accordance with some embodiments.

As shown in FIG. 3, the semiconductor device structure 300 is similar to the semiconductor device structure 200 of FIG. 2, except that the electrodes 182 are arranged in a triangular array, the trenches 132 are arranged in a triangular array, the electrodes 272 are arranged in a triangular array, and the trenches 232 are arranged in a triangular array, in accordance with some embodiments.

FIG. 4 is a top view of a semiconductor device structure, in accordance with some embodiments. It should be noted that, for the sake of simplicity, FIG. 4 omits depicting the dielectric layer 320, the conductive plugs 332 and 334, the conductive lines 342 and 344, and the dielectric layer 350 of the semiconductor device structure 100, in accordance with some embodiments.

As shown in FIG. 4, the semiconductor device structure 400 is similar to the semiconductor device structure 200 of FIG. 2, except that the electrodes 182, the trenches 132, the electrodes 272, and the trenches 232 have a rectangular shape, in accordance with some embodiments.

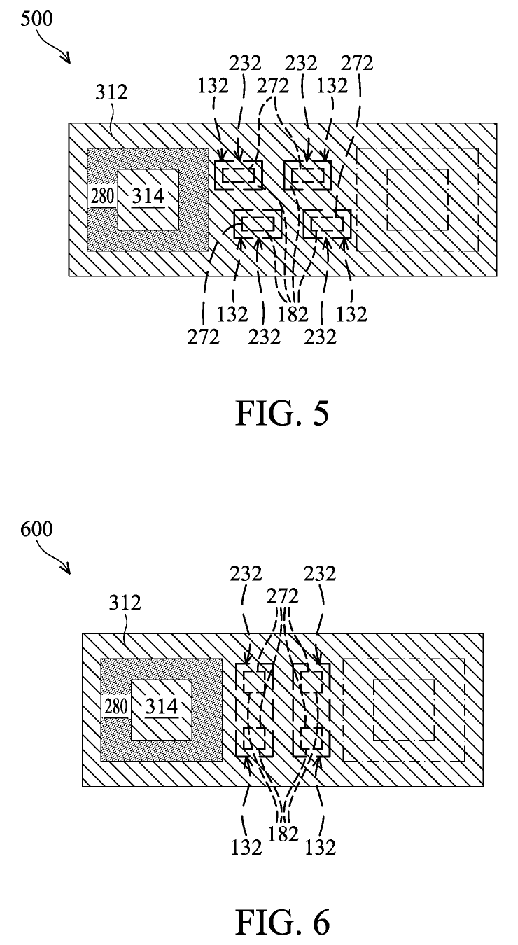

FIG. 5 is a top view of a semiconductor device structure 500, in accordance with some embodiments. It should be noted that, for the sake of simplicity, FIG. 5 omits depicting the dielectric layer 320, the conductive plugs 332 and 334, the conductive lines 342 and 344, and the dielectric layer 350 of the semiconductor device structure 100, in accordance with some embodiments.

As shown in FIG. 5, the semiconductor device structure 500 is similar to the semiconductor device structure 300 of FIG. 3, except that the electrodes 182, the trenches 132, the electrodes 272, and the trenches 232 have a rectangular shape, in accordance with some embodiments.

FIG. 6 is a top view of a semiconductor device structure 600, in accordance with some embodiments. It should be noted that, for the sake of simplicity, FIG. 6 omits depicting the dielectric layer 320, the conductive plugs 332 and 334, the conductive lines 342 and 344, and the dielectric layer 350 of the semiconductor device structure 100, in accordance with some embodiments.

As shown in FIG. 6, the semiconductor device structure 600 is similar to the semiconductor device structure 200 of FIG. 2, except that more than one electrode 272 overlaps one trench 232, and more than one electrode 182 overlaps one trench 132, in accordance with some embodiments.

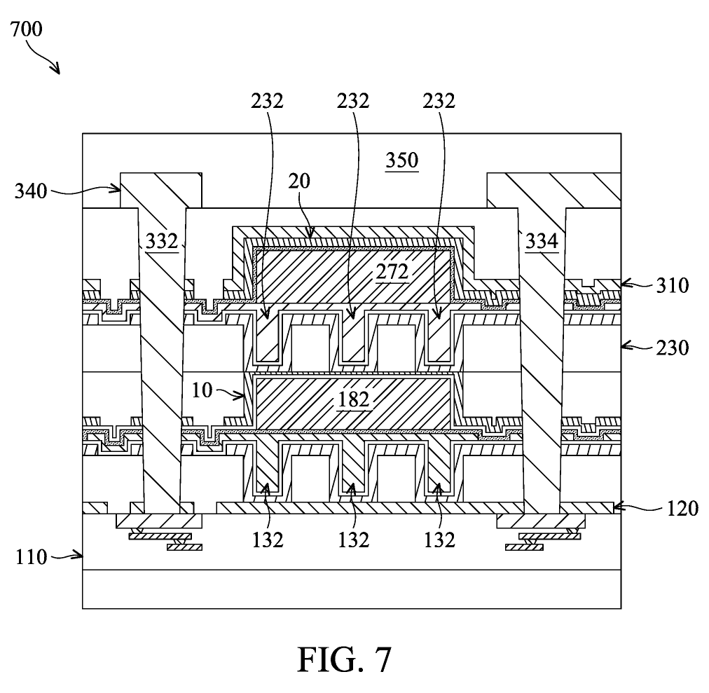

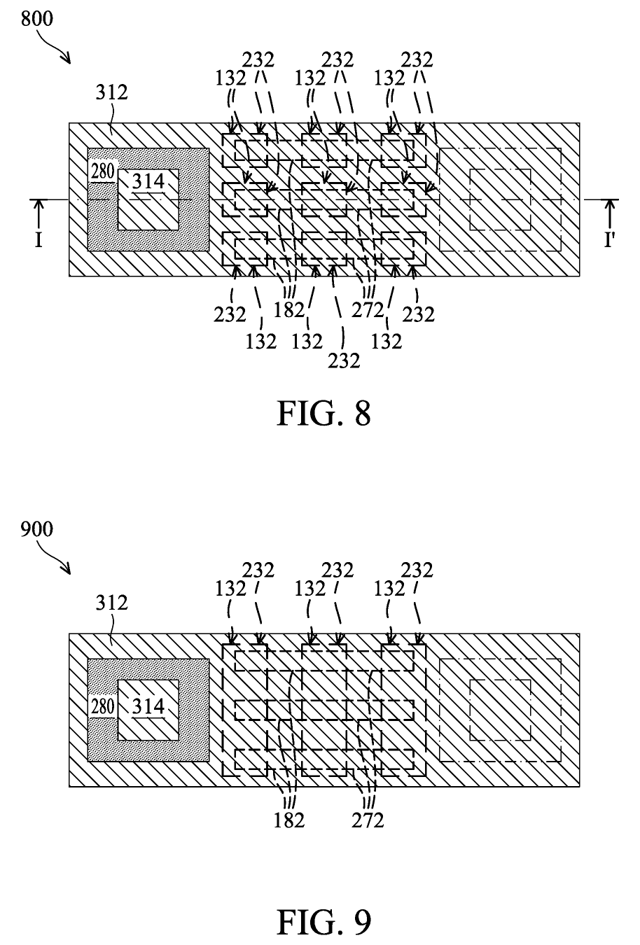

FIG. 7 is a cross-sectional view of a semiconductor device structure 700, in accordance with some embodiments. FIG. 8 is a top view of the semiconductor device structure 700, in accordance with some embodiments. FIG. 7 is a cross-sectional view illustrating the semiconductor device structure 700 along a sectional line I-I’ in FIG. 8, in accordance with some embodiments.

It should be noted that, for the sake of simplicity, FIG. 8 omits depicting the dielectric layer 320, the conductive plugs 332 and 334, the conductive lines 342 and 344, and the dielectric layer 350 of the semiconductor device structure 700, in accordance with some embodiments.

As shown in FIGS. 7 and 8, the semiconductor device structure 700 is similar to the semiconductor device structure 100 of FIG. 1M, except that each electrode 272 overlaps three trenches 232, and each electrode 182 overlaps three trenches 132, in accordance with some embodiments.

FIG. 9 is a top view of a semiconductor device structure 900, in accordance with some embodiments. It should be noted that, for the sake of simplicity, FIG. 9 omits depicting the dielectric layer 320, the conductive plugs 332 and 334, the conductive lines 342 and 344, and the dielectric layer 350 of the semiconductor device structure 700, in accordance with some embodiments.

As shown in FIG. 9, the semiconductor device structure 900 is similar to the semiconductor device structure 700 of FIG. 8, except that each trench 232 overlaps three electrodes 272, and each trench 132 overlaps three electrodes 182, in accordance with some embodiments.

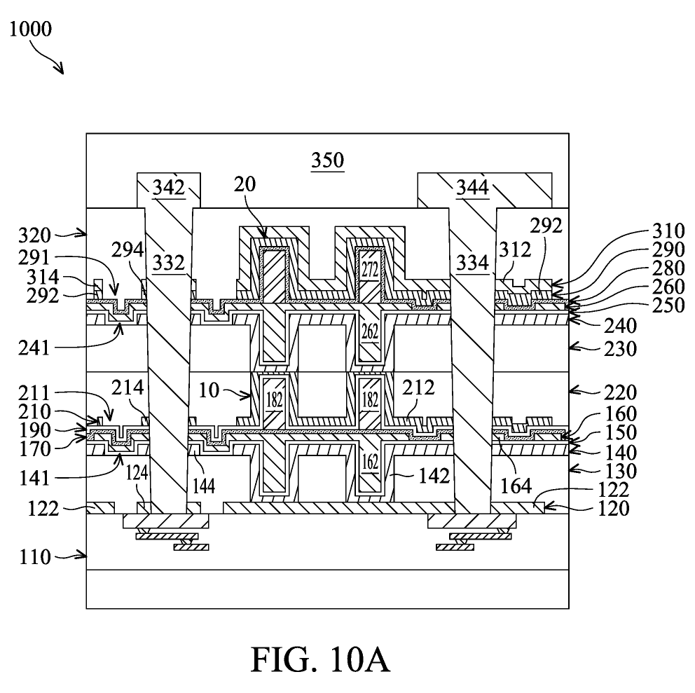

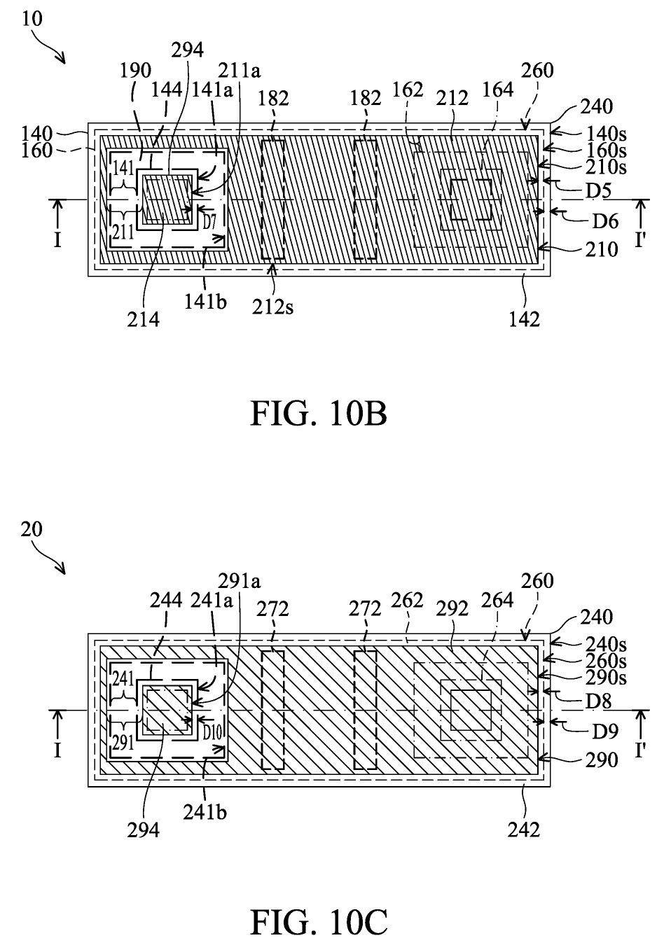

FIG. 10A is a cross-sectional view of a semiconductor device structure, in accordance with some embodiments. FIG. 10B is a top view of a first capacitor 10 of the semiconductor device structure of FIG. 10A, in accordance with some embodiments. FIG. 10C is a top view of a second capacitor 20 of the semiconductor device structure of FIG. 10A, in accordance with some embodiments.

FIG. 10A is a cross-sectional view illustrating the semiconductor device structure along a sectional line I-I’ in FIG. 10B, in accordance with some embodiments. FIG. 10A is a cross-sectional view illustrating the semiconductor device structure along a sectional line I-I’ in FIG. 10C, in accordance with some embodiments.

As shown in FIGS. 10A, 10B and 10C, the semiconductor device structure 1000 is similar to the semiconductor device structure 100 of FIG. 1M, except that the sidewalls of the conductive layers 140, 160, and 210 are miss-aligned with each other, and the sidewalls of the conductive layers 240, 250, and 290 are miss-aligned with each other, in accordance with some embodiments.

As shown in FIGS. 10A and 10B, the distance D5 between the sidewall 210s of the conductive layer 210 and the sidewall 160s of the conductive layer 160 ranges from about 0.05 μm to about 0.2 μm, in accordance with some embodiments.

The distance D6 between the sidewall 140s of the conductive layer 140 and the sidewall 160s of the conductive layer 160 ranges from about 0.05 μm to about 0.2 μm, in accordance with some embodiments. The distance D7 between the inner wall 211a of the trench 211 and the inner wall 141a of the trench 141 ranges from about 0.05 μm to about 0.2 μm, in accordance with some embodiments.

As shown in FIGS. 10A and 10C, the distance D8 between the sidewall 290s of the conductive layer 290 and the sidewall 260s of the conductive layer 260 ranges from about 0.05 μm to about 0.2 μm, in accordance with some embodiments.

The distance D9 between the sidewall 240s of the conductive layer 240 and the sidewall 260s of the conductive layer 260 ranges from about 0.05 μm to about 0.2 μm, in accordance with some embodiments. The distance D10 between the inner wall 291a of the trench 291 and the inner wall 241a of the trench 241 ranges from about 0.05 μm to about 0.2 μm, in accordance with some embodiments.

Processes and materials for forming the semiconductor device structures 200, 300, 400, 500, 600, 700, 900 and 1000 may be similar to, or the same as, those for forming the semiconductor device structure 100 described above. Elements designated by the same or similar reference numbers as those in FIGS. 1A-10C have the same or similar structures and the materials. Therefore, the detailed descriptions thereof will not be repeated herein.

In accordance with some embodiments, semiconductor device structures and methods for forming the same are provided. The methods (for forming the semiconductor device structure) form a conductive layer under a 3D capacitor and connected to a bottom portion of a bottom electrode of the 3D capacitor. The methods form a conductive plug passing through and electrically connected to the bottom electrode and the conductive layer. Since the bottom electrode has a non-straight line shape and the conductive layer has a straight line shape, the conductive layer can shorten the conductive path between the capacitor and the conductive plug. Therefore, the performance of the semiconductor device structure with the conductive layer is improved.

In accordance with some embodiments, a method for forming a semiconductor device structure is provided. The method includes forming a conductive layer over a substrate. The method includes forming a dielectric layer over the conductive layer and the substrate. The dielectric layer has a trench passing through the dielectric layer and exposing the conductive layer. The method includes forming a first electrode over the dielectric layer and in the trench. The first electrode is connected to the conductive layer. The method includes forming a first dielectric film over the first electrode. The method includes forming a second electrode over the first dielectric film. The first dielectric film electrically insulates the first electrode from the second electrode. The method includes forming a first conductive plug passing through the first electrode, the dielectric layer, and the conductive layer. The first conductive plug is electrically connected to the first electrode and the conductive layer.

In accordance with some embodiments, a method for forming a semiconductor device structure is provided. The method includes forming a dielectric layer over a conductive layer. The dielectric layer has a trench passing through the dielectric layer and exposing a portion of the conductive layer. The method includes forming a first electrode over the dielectric layer and in the trench. A bottom part of the first electrode is connected to the portion of the conductive layer. The method includes forming a first dielectric film over the first electrode. The method includes forming a second electrode over the first dielectric film. The first dielectric film electrically insulates the first electrode from the second electrode. The method includes forming a first conductive plug passing through the first electrode and the dielectric layer. The first conductive plug is electrically connected to the first electrode and the conductive layer, and a first portion of the conductive layer is between the second electrode and the first conductive plug and has a straight line shape in a cross-sectional view of the first electrode and the conductive layer.

In accordance with some embodiments, a semiconductor device structure is provided. The semiconductor device structure includes a substrate including a semiconductor substrate, a dielectric structure, and an interconnect structure. The dielectric structure is over the semiconductor substrate, the interconnect structure is in the dielectric structure and over a device region of the semiconductor substrate, and the interconnect structure includes metal lines. The semiconductor device structure includes a conductive layer over the substrate and electrically connected to the interconnect structure. The semiconductor device structure includes a dielectric layer over the conductive layer and the substrate. The semiconductor device structure includes a first electrode over the dielectric layer and passing through the dielectric layer. The first electrode is connected to the conductive layer. The semiconductor device structure includes a first dielectric film over the first electrode. The semiconductor device structure includes a second electrode over the first dielectric film. The first dielectric film electrically insulates the first electrode from the second electrode. The semiconductor device structure includes a first conductive plug passing through the first electrode, the dielectric layer, and the conductive layer. The first conductive plug is electrically connected to the first electrode and the conductive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a conductive layer over a substrate;
forming a dielectric layer over the conductive layer and the substrate, wherein the dielectric layer has a trench passing through the dielectric layer and exposing the conductive layer;
forming a first electrode over the dielectric layer and in the trench, wherein the first electrode is connected to the conductive layer;
forming a first dielectric film over the first electrode;
forming a second electrode over the first dielectric film, wherein the first dielectric film electrically insulates the first electrode from the second electrode; and
forming a first conductive plug passing through the first electrode, the dielectric layer, and the conductive layer, wherein the first conductive plug is electrically connected to the first electrode and the conductive layer.

2. The method for forming the semiconductor device structure as claimed in claim 1, further comprising:
forming a second conductive plug passing through the second electrode, wherein the second conductive plug is electrically connected to the second electrode.

3. The method for forming the semiconductor device structure as claimed in claim 1, wherein the conductive layer has a straight line shape in a cross-sectional view of the first electrode, the conductive layer, and the second electrode.

4. The method for forming the semiconductor device structure as claimed in claim 3, wherein the first electrode has a U-like shape in the cross-sectional view.

5. The method for forming the semiconductor device structure as claimed in claim 3, wherein the second electrode has a T-like shape in the cross-sectional view.

6. The method for forming the semiconductor device structure as claimed in claim 1, further comprising:
forming a third electrode over the second electrode, wherein the third electrode is over the trench.

7. The method for forming the semiconductor device structure as claimed in claim 6, further comprising:
forming a second dielectric film over the second electrode before the third electrode is formed, wherein the third electrode is formed over the second dielectric film.

8. The method for forming the semiconductor device structure as claimed in claim 7, further comprising:
forming a third dielectric film over the third electrode; and
forming a fourth electrode over the third dielectric film.

9. The method for forming the semiconductor device structure as claimed in claim 1, further comprising:
forming a second dielectric film over the third electrode; and
forming a fourth electrode over the second dielectric film.

10. The method for forming the semiconductor device structure as claimed in claim 9, wherein the first conductive plug further passes through and is electrically connected to the fourth electrode.

11. A method for forming a semiconductor device structure, comprising:
forming a dielectric layer over a conductive layer, wherein the dielectric layer has a trench passing through the dielectric layer and exposing a portion of the conductive layer;
forming a first electrode over the dielectric layer and in the trench, wherein a bottom part of the first electrode is connected to the portion of the conductive layer;
forming a first dielectric film over the first electrode;
forming a second electrode over the first dielectric film, wherein the first dielectric film electrically insulates the first electrode from the second electrode; and
forming a first conductive plug passing through the first electrode and the dielectric layer, wherein the first conductive plug is electrically connected to the first electrode and the conductive layer, and a first portion of the conductive layer is between the second electrode and the first conductive plug and has a straight line shape in a cross-sectional view of the first electrode and the conductive layer.

12. The method for forming the semiconductor device structure as claimed in claim 11, wherein a second portion of the first electrode is between the second electrode and the first conductive plug and has an L-like shape in the cross-sectional view.

13. The method for forming the semiconductor device structure as claimed in claim 12, wherein a third portion of the dielectric layer is surrounded by the first portion of the conductive layer, the second portion of the first electrode, and the first conductive plug.

14. The method for forming the semiconductor device structure as claimed in claim 11, further comprising:
forming a second conductive plug passing through the second electrode, wherein the second conductive plug is electrically connected to the second electrode.

15. The method for forming the semiconductor device structure as claimed in claim 14, wherein the first portion of the conductive layer is between the first conductive plug and the second conductive plug.

16. A semiconductor device structure, comprising:
a substrate comprising a semiconductor substrate, a dielectric structure, and an interconnect structure, wherein the dielectric structure is over the semiconductor substrate, the interconnect structure is in the dielectric structure and over a device region of the semiconductor substrate, and the interconnect structure comprises metal lines;
a conductive layer over the substrate and electrically connected to the interconnect structure;
a dielectric layer over the conductive layer and the substrate;
a first electrode over the dielectric layer and passing through the dielectric layer, wherein the first electrode is connected to the conductive layer;
a first dielectric film over the first electrode;
a second electrode over the first dielectric film, wherein the first dielectric film electrically insulates the first electrode from the second electrode; and
a first conductive plug passing through the first electrode, the dielectric layer, and the conductive layer, wherein the first conductive plug is electrically connected to the first electrode and the conductive layer.

17. The semiconductor device structure as claimed in claim 16, wherein a first portion of the first electrode is between the second electrode and the first conductive plug and has an L-like shape in a cross-sectional view of the first electrode and the conductive layer.

18. The semiconductor device structure as claimed in claim 17, wherein a second portion of the conductive layer is between the second electrode and the first conductive plug and has a straight line shape in the cross-sectional view.

19. The semiconductor device structure as claimed in claim 16, further comprising:
a second conductive plug pass through the second electrode, wherein the second conductive plug is electrically connected to the second electrode.

20. The semiconductor device structure as claimed in claim 19, wherein a portion of the conductive layer is between the first conductive plug and the second conductive plug.
